(19) United States
(12) Patent Application Publication
(10) Pub. No.: US 2025/0194327 A1
(43) Pub. Date: Jun. 12, 2025

(54) ARRAY SUBSTRATE, LIGHT-EMITTING SUBSTRATE, BACKLIGHT MODULE, AND DISPLAY APPARATUS

(71) Applicants: Hefei BOE Ruisheng Technology Co., Ltd., Hefei, Anhui (CN); BOE TECHNOLOGY GROUP CO., LTD., Beijing (CN)

(72) Inventors: Jian TIAN, Beijing (CN); Jie LEI, Beijing (CN); Chunjian LIU, Beijing (CN); Jianying ZHANG, Beijing (CN); Yajun MA, Beijing (CN); Wenbo DONG, Beijing (CN); Hong JIN, Beijing (CN)

(73) Assignees: Hefei BOE Ruisheng Technology Co., Ltd., Hefei, Anhui (CN); BOE TECHNOLOGY GROUP CO., LTD., Beijing (CN)

(21) Appl. No.: 18/840,082

(22) PCT Filed: Dec. 7, 2023
(86) PCT No.: PCT/CN2023/137057

§ 371 Date: Aug. 21, 2024

(51) Int. Cl. H10H 29/49; G02F 1/13357; H10H 29/853

(52) U.S. Cl. CPC H10H 29/49; G02F 1/133603; G02F 1/133606; H10H 29/853

(57) ABSTRACT

An array substrate includes a substrate, a first conductive layer, at least one insulating layer disposed on a side of the first conductive layer away from the substrate, and a second conductive layer disposed on a side of the at least one insulating layer away from the substrate. The first conductive layer includes a plurality of signal lines, and the plurality of signal lines include device power supply lines. The at least one insulating layer is provided with a first via hole therein. The second conductive layer includes a plurality of device conductive portion groups and a plurality of chip conductive portion groups. A device conductive portion group includes first conductive portions at intervals. A chip conductive portion group includes second conductive portions at intervals. A first conductive portion of the device conductive portion group is in electrical contact with a device power line through the first via hole.

### CROSS-REFERENCE TO RELATED APPLICATION

This application is a national phase entry under 35 USC 371 of International Patent Application No. PCT/CN2023/137057, filed on Dec. 7, 2023, which is incorporated herein by reference in its entirety.

### TECHNICAL FIELD

The present disclosure relates to the field of display technologies, and in particular, to an array substrate, a light-emitting substrate, a backlight module, and a display apparatus.

### BACKGROUND

With the development of light-emitting diode technologies, backlight sources using light-emitting diodes (LEDs) with sub-millimeter (micro) scale and even micron (mini) scale have been widely used. Therefore, not only may an image contrast of a product such as a liquid crystal display (LCD) using the backlight source reach a level of an organic light-emitting diode (OLED) display product, but also the product may retain the technical advantages of liquid crystal display, thereby further a display effect of the image and providing users with a good visual experience.

### SUMMARY

In an aspect, an array substrate is provided. The array substrate includes a substrate, a first conductive layer, at least one insulating layer and a second conductive layer. The first conductive layer is disposed on a side of the substrate. The first conductive layer includes a plurality of signal lines, and the plurality of signal lines include a plurality of device power supply lines. The at least one insulating layer id disposed on a side of the first conductive layer away from the substrate, and the at least one insulating layer is provided with first via holes extending through the at least one insulating layer. The second conductive layer is disposed on a side of the at least one insulating layer away from the substrate. The second conductive layer includes a plurality of device conductive portion groups and a plurality of chip conductive portion groups. A device conductive portion group includes a plurality of first conductive portions disposed at intervals, and the device conductive portion group is configured to be connected to a light-emitting device. A chip conductive portion group includes a plurality of second conductive portions disposed at intervals, and the chip conductive portion group is configured to be connected to a microchip. A first conductive portion of the device conductive portion group is in electrical contact with a device power line through a first via hole.

In some embodiments, the array substrate includes a plurality of light-emitting units and a plurality of connection lines. A light-emitting unit includes multiple device conductive portion groups connected in series and/or in parallel in the plurality of device conductive portion groups, and the multiple device conductive portion groups in the same light-emitting unit are connected by connection lines. At least one connection line is located in the first conductive layer.

In some embodiments, the plurality of connection lines include first type of connection lines and second type of connection lines. Orthographic projections of the first type of connection lines on the substrate are staggered with orthographic projections of the plurality of signal lines on the substrate, and orthographic projections of the second type of connection lines on the substrate at least partially overlap with the orthographic projections of the plurality of signal lines on the substrate. All the first type of connection lines are located in the first conductive layer, and all the second type of connection lines are located in the second conductive layer.

In some embodiments, the plurality of signal lines further include a plurality of common voltage signal lines and a plurality of chip signal lines. The plurality of chip signal lines are divided into a plurality of chip signal line groups, and multiple chip signal lines of each chip signal line group are configured to be connected to a same microchip.

The plurality of device power lines, the plurality of common voltage signal lines and the plurality of chip signal lines all extend in a first direction. In a second direction, each chip signal line group is located between two common voltage signal lines, and each common voltage signal line is located between a chip signal line group and a device power line. The first direction intersects the second direction. A first type of connection line is located between the device power line and a common voltage signal line that are adjacent to the first type of connection line; and/or another first type of connection line is located between the common voltage signal line and a chip signal line group that are adjacent to the another first type of connection line.

In some embodiments, the light-emitting unit includes a first device conductive portion group, a second device conductive portion group, a third device conductive portion group and a fourth device conductive portion group. The first device conductive portion group is connected to the device power line, and the fourth device conductive portion group is connected to the chip conductive portion group.

The plurality of connection lines include a first connection line, a second connection line and a third connection line. An end of the first connection line is connected to the first device conductive portion group, and another end of the first connection line is connected to the second device conductive portion group. The first connection line is located in the first conductive layer. An end of the second connection line is connected to the second device conductive portion group, and another end of the second connection line is connected to the third device conductive portion group. The second connection line is located in the second conductive layer. An end of the third connection line is connected to the third device conductive portion group, and another end of the third connection line is connected to the fourth device conductive portion group. The third connection line being located in the first conductive layer.

In some embodiments, the device power line includes a main body portion, a first overlapping portion and a second overlapping portion. The main body portion extends in a first direction. In a second direction, at least one side of the main body portion is provided with a plurality of first openings and a plurality of second openings therein, and in the first direction, the plurality of first openings and the plurality of second openings are disposed alternately. The first direction intersects the second direction. The first overlapping portion is connected to the main body portion and located at a first opening. The second overlapping portion is connected to the main body portion and located between the first opening and a second opening that are adjacent. The second overlapping portion includes a first sub-segment and a second sub-segment. The first sub-segment extends in the first direction, the second sub-segment extends in the second direction, and the first sub-segment is located on a side of the second sub-segment proximate to the adjacent first opening.

In some embodiments, edges, close to each other, of the first sub-segment and the main body portion coincide. Alternatively, the first sub-segment and the main body portion have a gap therebetween; the second overlapping portion further includes a third sub-segment, and the first sub-segment is connected to the main body portion by the third sub-segment.

In some embodiments, an end of the first sub-segment away from the second sub-segment is flush with an edge of the first opening proximate to the second opening.

In some embodiments, the array substrate includes a plurality of light-emitting units, and the plurality of light-emitting units are arranged in an array in the first direction and the second direction. The light-emitting units each include multiple device conductive portion groups connected in series and/or in parallel in the plurality of device conductive portion groups, the multiple device conductive portion groups include a target device conductive portion group, and the target device conductive portion group is the device conductive portion group, in electrical contact with the device power line through the first via hole, in the multiple device conductive portion groups.

In the first direction, in two adjacent light-emitting units, a first conductive portion of a target device conductive portion group of a light-emitting unit is in electrical contact with the first overlapping portion through a first via hole, and a first conductive portion of a target device conductive portion group of another light-emitting unit is in electrical contact with the second sub-segment through another first via hole.

In some embodiments, the plurality of signal lines further include a plurality of chip signal lines and a plurality of common voltage signal lines. The plurality of chip signal lines are divided into a plurality of chip signal line groups, and multiple chip signal lines of each chip signal line group are configured to be connected to a same microchip. The plurality of device power lines, the plurality of common voltage signal lines and the plurality of chip signal lines all extend in a first direction. In a second direction, each chip signal line group is located between two common voltage signal lines, and each common voltage signal line is located between a chip signal line group and a device power line. The first direction intersects the second direction.

The chip conductive portion group is located between two adjacent chip signal lines in a same chip signal line group. The at least one insulating layer is further provided with second via holes and third via holes extending through the at least one insulating layer. The array substrate further includes a plurality of first transfer lines, and a first transfer line includes a first trace segment and a second trace segment. The first trace segment is disposed in the first conductive layer and located between a common voltage signal line and a chip signal line that are adjacent to the first trace segment. A first conductive portion of the device conductive portion group is in electrical contact with the first trace segment through a second via hole. The second trace segment is disposed in the second conductive layer. An end of the second trace segment is in electrical contact with the first trace segment through a third via hole, and another end of the second trace segment crosses at least one chip signal line to be connected to a second conductive portion of the chip conductive portion group.

In some embodiments, the chip conductive portion group has a center line extending in the first direction, and a maximum distance between the third via hole and the center line is less than or equal to 2 mm.

In some embodiments, the at least one insulating layer is further provided with fourth via holes and fifth via holes extending through the at least one insulating layer. The array substrate further includes a plurality of second transfer lines and a plurality of third transfer lines. The plurality of second transfer lines are disposed in the second conductive layer. An end of a second transfer line is connected to the chip signal line through a fourth via hole, and another end of the second transfer line is connected to a second conductive portion of the chip conductive portion group. The plurality of third transfer lines are disposed in the second conductive layer. An end of a third transfer line is connected to the common voltage signal line through a fifth via hole, and another end of the third transfer line crosses at least one chip signal line to be connected to a second conductive portion of the chip conductive portion group.

In some embodiments, the second conductive layer further includes a third conductive portion. The array substrate further includes first test lines, the third conductive portion is connected to a signal line by a first test line, and at least one first test lines is located in the first conductive layer.

In some embodiments, the array substrate includes a plurality of light-emitting units, a plurality of connection lines and a plurality of first transfer lines. A light-emitting unit includes multiple device conductive portion groups connected in series and/or in parallel in the plurality of device conductive portion groups, and the multiple device conductive portion groups in the same light-emitting unit are connected by connection lines. The light-emitting unit is connected to the chip conductive portion group by a first transfer line. The array substrate further includes second test lines, the third conductive portion is connected to a connection line or the first transfer line by a second test line, and at least one second test line is located in the first conductive layer.

In some embodiments, the at least one insulating layer includes a first passivation layer, a first planarization layer and a second passivation layer that are disposed sequentially, and the second passivation layer is disposed on a side of the first planarization layer away from the first conductive layer. And/or, the array substrate further includes a third passivation layer, and the third passivation layer is disposed on a side of the second conductive layer away from the substrate.

In another aspect, a light-emitting substrate is provided. The light-emitting substrate includes an array substrate, a light-emitting device and a microchip. The array substrate is the array substrate as described in any of the above embodiments, the light-emitting device is connected to the device conductive portion group of the array substrate, and the microchip is connected to the chip conductive portion group of the array substrate.

In some embodiments, the light-emitting substrate further includes a first encapsulation layer. The first encapsulation layer covers the microchip. In a case where the at least one insulating layer is further provided with a third via hole and a fourth via hole extending through the at least one insulating layer, the first encapsulation portion further covers the third via hole and the fourth via hole.

In yet another aspect, a backlight module is provided. The backlight module includes the light-emitting substrate as described in any of the above embodiments and a plurality of optical films. The light-emitting substrate has a light-exit side and a non-light-exit side that are opposite to each other. The plurality of optical films are disposed on the light-exit side of the light-emitting substrate.

In yet another aspect, a display apparatus is provided. The display apparatus includes the backlight module as described in any of the above embodiments and a display panel. The display panel is disposed on a side of the plurality of optical films in the backlight module away from the light-emitting substrate.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a structural diagram of another display apparatus, in accordance with some embodiments;

FIG. 3 is a sectional view of the display apparatus, in accordance with some embodiments;

FIG. 4 is a top view of a light-emitting substrate, in accordance with some embodiments;

FIG. 5 is a circuit diagram of a light-emitting substrate, in accordance with some embodiments;

FIG. 6 is a wiring layout diagram of an array substrate, in accordance with some embodiments;

FIG. 7 is a sectional view of the array substrate shown in FIG. 6 taken along a section line A-A;

FIGS. 8, 9 and 10 are each a schematic diagram of different degrees of layering of a connection trace in a via hole and a device power line in the related art;

FIG. 11 is a partial enlarged view of the array substrate shown in FIG. 6 at a region C;

FIG. 12 is a partial enlarged view of the array substrate shown in FIG. 6 at a region D;

FIG. 13 is another partial enlarged view of the array substrate shown in FIG. 6 at a region D;

FIG. 14 is a diagram showing a reliability test result of circuit lines located in a second conductive layer, in accordance with some embodiments;

FIG. 15 is a structural diagram of a device power line, in accordance with some embodiments;

FIG. 16 is a structural diagram of another device power line, in accordance with some embodiments;

FIG. 17 is a line graph of a spacing between circuit lines in a first conductive layer of an array substrate and a thickness uniformity of the first conductive layer, in accordance with some embodiments;

FIG. 18 is a sectional view of the array substrate shown in FIG. 6 taken along a section line B-B;

FIG. 19 is a wiring layout diagram of a light-emitting substrate, in accordance with some embodiments;

FIG. 20 is a partial enlarged view of the light-emitting substrate shown in FIG. 19 at a region E;

FIG. 21 is a partial enlarged view of the array substrate shown in FIG. 6 at a region F; and

FIG. 22 is a partial enlarged view of the array substrate shown in FIG. 6 at a region G.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

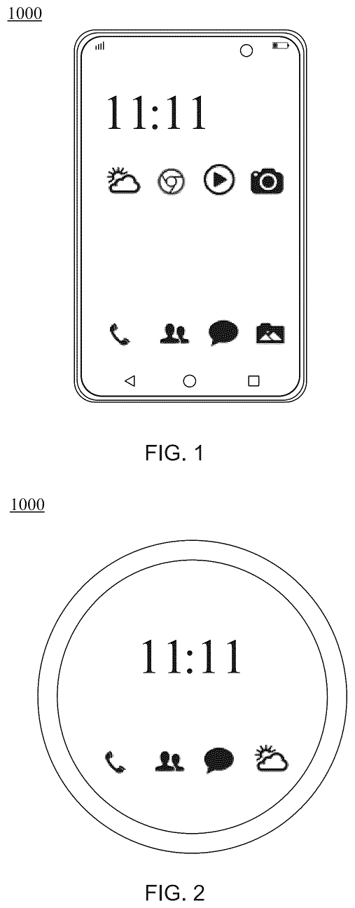

As shown in FIG. 1, some embodiments of the present disclosure provide a display apparatus 1000, and the display apparatus 1000 may be any apparatus that displays images whether in motion (e.g., video) or stationary (e.g., still images), and regardless of text or image.

For example, referring to FIG. 1, the display apparatus 1000 may be any product or component having a display function, such as a television, a notebook computer, a tablet computer, a mobile phone, a personal digital assistant (PDA), a navigator, a wearable device, or a virtual reality (VR) device.

For example, as shown in FIG. 1, the display apparatus 1000 may be a portable display product; for example, the display apparatus 1000 may be a mobile phone shown in FIG. 1. As another example, referring to FIG. 2, the display apparatus 1000 may be a wearable device; for example, the display apparatus 1000 may be a watch shown in FIG. 2.

It will be noted that, depending on different application scenarios, a shape of a display surface of the display apparatus 1000 is not unique, and the shape of the display surface of the display apparatus 1000 may be any of a circle, an ellipse or a polygon, which is not specifically limited in the embodiments of the present disclosure.

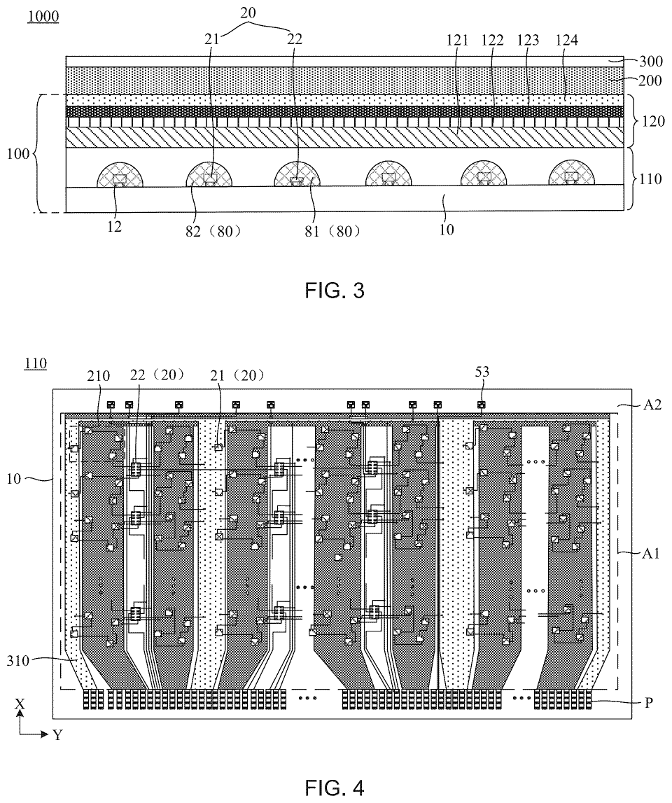

In some embodiments, the display apparatus 1000 may be a liquid crystal display (LCD) device. In some embodiments, referring to FIG. 3, the display apparatus 1000 may be a liquid crystal display (LCD).

For example, referring to FIG. 3, the display apparatus 1000 includes a backlight module 100, a display panel 200 and a cover plate 300. The display panel 200 is disposed on a side of the backlight module 100 from which light exits, and the cover plate 300 is disposed on a side of the display panel 200 away from the backlight module 100.

Referring to FIG. 3, the backlight module 100 includes a light-emitting substrate 110, and the light-emitting substrate 110 has a light-exit side and a non-light-exit side that are opposite to each other. The light-exit side refers to a side of the light-emitting substrate 110 from which light exits (an upper side of the light-emitting substrate 110 in FIG. 3), that is, the side of the backlight module 100 from which the light exits; and the non-light-exit side refers to the other side opposite to the light-exit side (a lower side of the light-emitting substrate 110 in FIG. 3).

In some embodiments, as shown in FIG. 3, the backlight module 100 further includes a plurality of optical films 120, and the plurality of optical films 120 are located at the light-exit side of the light-emitting substrate 100. The display panel 200 is disposed on a side of the plurality of optical films 120 away from the light-emitting substrate 110.

The light emitted from the light-emitting substrate 110 passes through the optical films 120 and then is directed toward the display panel 200. That is, the display panel 200 is disposed on a side of the optical films 120 away from the light-emitting substrate 110. It will be noted that the optical films 120 perform modulation on a wavelength and/or a propagation direction of light emitted from the light-emitting substrate 110.

As shown in FIG. 3, the light-emitting substrate 110 may directly emit white light, and a propagation direction of the white light, after passing through the plurality of optical films 120, is modulated and then directed toward the display panel 200. Alternatively, the light-emitting substrate 110 may emit light of other colors (e.g., blue light), which is then directed toward the display panel 200 after undergoing modulation of a wavelength and/or a propagation direction of the light by the plurality of optical films 120.

For example, referring to FIG. 3, the plurality of optical films 120 include a scattering layer 121, a color conversion layer 122, a diffusion sheet 123 and a composite film 124. The scattering layer 121, the color conversion layer 122, the diffusion sheet 123 and the composite film 124 are, for example, sequentially disposed away from the display panel 200. That is, the diffusion sheet 123 may be provided on the light-exit side of the light-emitting substrate 110, the composite film 124 is provided on a side of the diffusion sheet 123 away from the light-emitting substrate 110, the scattering layer 121 and the color conversion layer 122 are provided on a side of the diffusion sheet 123 proximate to the light-emitting substrate 110, and the display panel 200 is provided on a side of the composite film 124 away from the light-emitting substrate 110.

The scattering layer 121 can blur the light emitted by the light-emitting substrate 110, and provide support for the color conversion layer 122, the diffusion sheet 123 and the composite film 124. The color conversion layer 122 may, under excitation of light of a certain color emitted by the light-emitting substrate 110, convert the light into white light to improve a utilization rate of the light energy of the light-emitting substrate 110. The diffusion sheet 123 can perform uniform processing on the light passing through the diffusion sheet 123. The composite film 124 can improve the light extraction efficiency of the light-emitting substrate 110, thereby increasing the display brightness of the display apparatus 1000.

It will be noted that the composite film 124 may include a brightness enhancement film (BEF) and a reflective polarizing brightness enhancement film (also called a dual brightness enhancement film (DBEF)), and utilizes principles of total reflection, refraction and polarization to increase a light flux within a certain angle range, thereby improving the brightness of the display apparatus 1000.

For example, referring to FIG. 3, the light-emitting substrate 110 emits blue light. The color conversion layer 122 may include a red quantum dot material, a green quantum dot material and a transparent material. When the blue light emitted by the light-emitting substrate 110 passes through the red quantum dot material, the blue light is converted into red light; when the blue light passes through the green quantum dot material, the blue light is converted into green light; and the blue light may directly pass through the transparent material. Then, the blue light, the red light and the green light are mixed and superimposed in a certain proportion to present white light. Finally, the scattering layer 121 and the diffusion sheet 123 can modulate the incident light in different propagation directions and allow the light to exit in a uniform state, so as to improve a light shadow produced by the light-emitting substrate 110 and enhance a display quality of the display apparatus 1000.

In some embodiments, with reference to FIG. 4, the light-emitting substrate 110 has a light-emitting area A1 and a peripheral area A2 located on at least one side of the light-emitting area A1.

The light-emitting area A1 is configured to provide with electronic components 20 therein, and the electronic components 20 include, for example, light-emitting devices 21 and/or microchips 22. The peripheral area A2 is configured to be bonded the circuit board, for example, the peripheral area A2 is provide with a plurality of bonding pads P therein.

For example, referring to FIGS. 3 and 4, the light-emitting substrate 110 includes an array substrate 10 and electronic components 20. The electronic components 20 are disposed on the array substrate 10 and located in the light-emitting area A1.

Referring to FIG. 4, the electronic components 20 may include light-emitting devices 21 and/or microchips 22.

As shown in FIG. 4, the light-emitting devices 21 may include micro LEDs and mini LEDs. A dimension (e.g., a length) of the micro LED is less than 50 μm, for example, in a range of 10 μm to 50 μm. A dimension (e.g., a length) of the mini LED is in a range of 50 μm to 150 μm, for example, in a range of 80 μm to 120 μm, inclusive.

As shown in FIG. 4, the microchips 22 may include sensor chip(s) and a driver chip. The sensor chip is, for example, a photosensitive sensor chip or a thermal sensor chip. The driver chip is used to provide a driving signal to the light-emitting device 21.

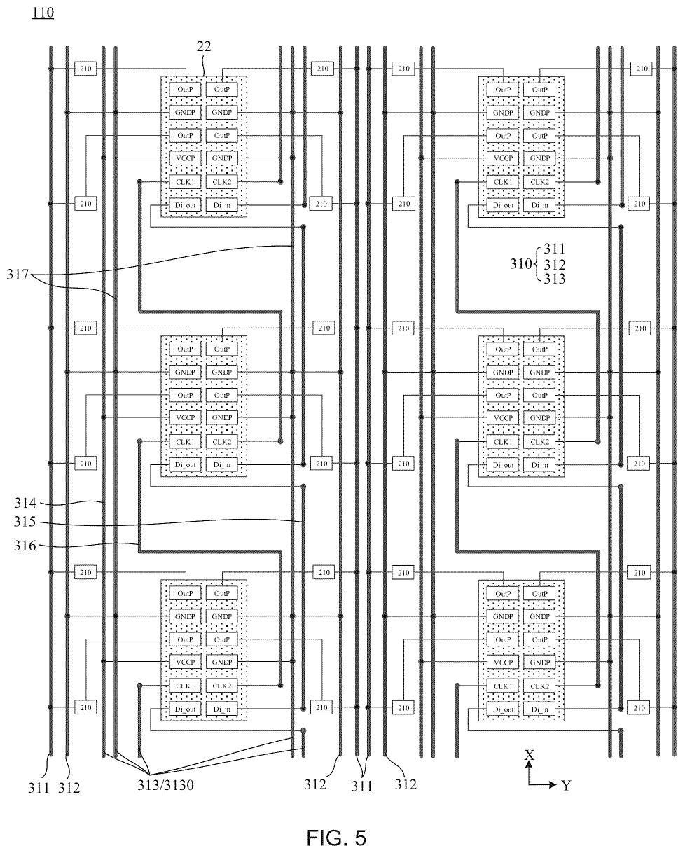

In some embodiments, as shown in FIGS. 4 and 5, the light-emitting substrate 110 includes a plurality of light-emitting units 210, the plurality of light-emitting units 210 are arranged in an array of a plurality of rows and a plurality of columns, each column includes multiple light-emitting units 210 arranged in a first direction X, and each row includes multiple light-emitting units 210 arranged in a second direction Y. The first direction X intersects the second direction Y. For example, the first direction X is perpendicular to the second direction Y.

It will be noted that herein, the multiple light-emitting units 210 arranged in the first direction X are referred to as a column of light-emitting units 210, and the multiple light-emitting units 210 arranged in the second direction Y are referred to as a row of light-emitting units 210.

Each light-emitting unit 210 includes a plurality of light-emitting devices 21 connected in series and/or in parallel. For example, as shown in FIG. 4, each light-emitting unit 210 includes four light-emitting devices 21 sequentially connected in series. Of course, each light-emitting unit 210 may alternatively include four, five, seven or eight light-emitting devices 21, and a connection manner of the plurality of light-emitting devices 21 in the light-emitting unit 210 is not limited to a connection in series, but may also be a connection in parallel.

Some embodiments of the present disclosure are schematically described below by taking an example where the light-emitting unit 210 includes four light-emitting devices 21 sequentially connected in series, but the embodiments of the present disclosure are not limited thereto.

In addition, the microchip 22 is, for example, a driver chip for driving the plurality of light-emitting devices 21 to emit light. Here, a microchip 22 may only drive a plurality of light-emitting devices 21 in a light-emitting unit 210 correspondingly to emit light; alternatively, a microchip 22 may drive a plurality of light-emitting devices 21 in a plurality of light-emitting units 210 to emit light.

For example, as shown in FIGS. 4 and 5, four light-emitting units 210 arranged adjacently in two rows and two columns are electrically connected to the same microchip 22, and the microchip 22 is electrically connected to each of the four light-emitting units 210 to drive a plurality of light-emitting devices 21 in the four light-emitting units 210 to emit light.

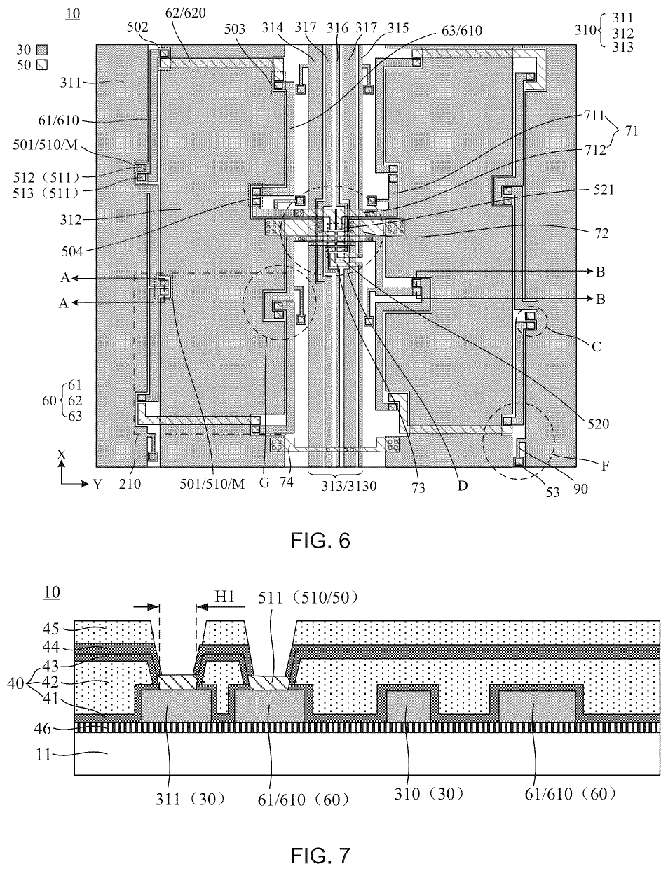

In some embodiments, as shown in FIGS. 6 and 7, the array substrate 10 includes a substrate 11, a first conductive layer 30, at least one insulating layer 40 and a second conductive layer 50.

As shown in FIG. 7, the substrate 11 may be a rigid substrate or a flexible substrate. The material of the rigid substrate includes at least one of glass, quartz, sapphire, ceramic and polymethyl methacrylate (PMMA). The material of the flexible substrate includes at least one of epoxy resin, triazine, silicone resin and polyimide.

As shown in FIG. 7, the first conductive layer 30 is disposed on a side of the substrate 11, the insulating layer(s) 40 are disposed on a side of the first conductive layer 30 away from the substrate 11, and the second conductive layer 50 is disposed on a side of the insulating layer(s) 40 away from the substrate 11.

It will be noted that the materials of the first conductive layer 30 and the second conductive layer 50 each include at least one of copper, molybdenum-niobium alloy, nickel and indium tin oxide.

As shown in FIG. 7, the at least one insulating layer 40 includes, for example, a first passivation layer 41, a first planarization layer 42 and a second passivation layer 43 that are provided in sequence, and the second passivation layer 43 is provided on a side of the first planarization layer 42 away from the first conductive layer 30. That is, the first passivation layer 41 is in contact with the first conductive layer 30, and the second passivation layer 43 is in contact with the second conductive layer 50.

In addition, as shown in FIG. 7, the array substrate 10 may further include a third passivation layer 44, a second planarization layer 45 and a buffer layer 46. The third passivation layer 44 is provided on a side of the second conductive layer 50 away from the substrate 11, the second planarization layer 45 is provided on a side of the third passivation layer 44 away from the substrate 11, and the buffer layer 46 is provided between the substrate 11 and the first conductive layer 30.

It will be noted that the array substrate 10 may not include the second planarization layer 45 and the buffer layer 46, which is not specifically limited in the embodiments of the present disclosure.

The materials of the first passivation layer 41, the second passivation layer 43, the third passivation layer 44 and the buffer layer 46 may each include at least one of inorganic insulating materials such as silicon nitride, silicon oxynitride and silicon oxide. For example, the materials of the first passivation layer 41, the second passivation layer 43 and the third passivation layer 44 each include silicon nitride.

A thickness of each of the first passivation layer 41, the second passivation layer 43 and the third passivation layer 44 is in a range of 1200 Å to 6000 Å, inclusive. For example, the thicknesses of the first passivation layer 41 and the second passivation layer 43 are each any of 1200 Å, 1500 Å, 2000 Å, 2500 Å, 2800 Å, 3000 Å, 3300 Å, 3500 Å, 4000 Å, 4500 Å, 4800 Å, 5000 Å, 5200 Å, 5500 Å and 6000 Å. The material of the first planarization layer 42 includes resin. For example, the material of the first planarization layer 42 includes epoxy resin.

The materials of the first planarization layer 42 and the second planarization layer 45 each include transparent resin. For example, the materials of the first planarization layer 42 and the second planarization layer 45 each include epoxy resin.

A total thickness of the first planarization layer 42 and the second planarization layer 45 is in a range of 4 μm to 10 μm, inclusive. For example, the total thickness of the first planarization layer 42 and the second planarization layer 45 is any of 4 μm, 4.5 μm, 5 μm, 5.5 μm, 6 μm, 6.5 μm, 7 μm, 7.5 μm, 8 μm, 8.5 μm, 9 μm, 9.5 μm and 10 μm. The thickness of the first planarization layer 42 and the thickness of the second planarization layer 45 may be designed according to actual conditions, and are not specifically limited in the embodiments of the present disclosure.

In the related art, signal lines are arranged in the first conductive layer 30′, and connection traces 51′ are arranged in the second conductive layer 50′. The light-emitting devices and the microchip are connected to corresponding signal lines by connection traces 51′, and a plurality of light-emitting devices in the same light-emitting unit are connected by connection trace(s) 51′.

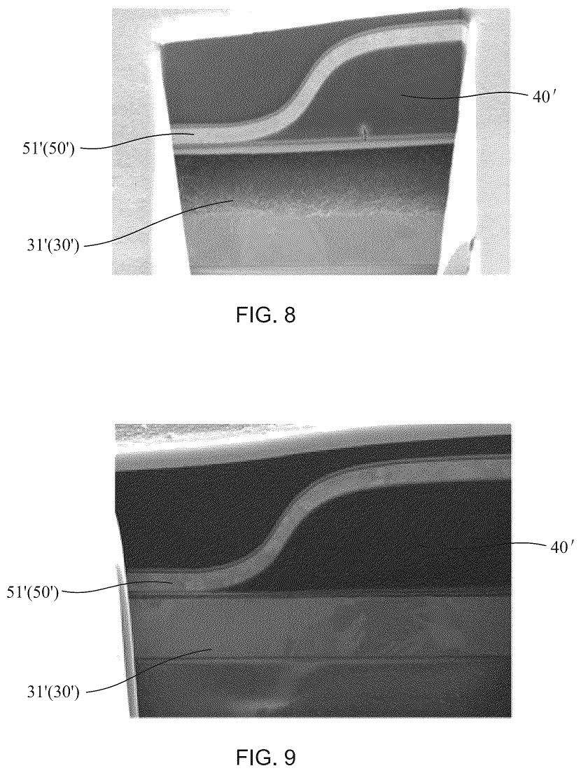

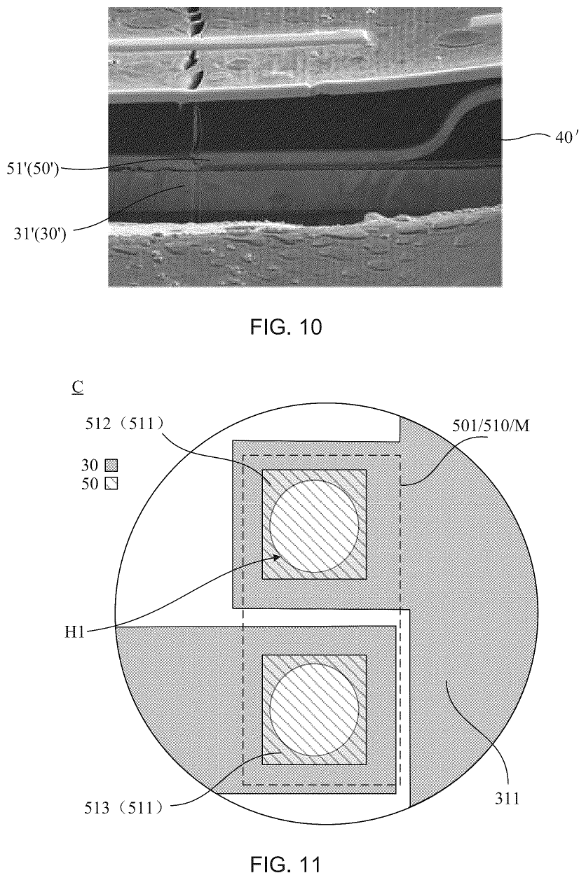

The signal lines include a device power line 31′, the light-emitting device is connected to the device power line 31′ by a connection trace 51′, and the connection trace 51′ needs to be connected to the device power line 31′ through a via hole extending through the insulating layer(s) 40′. However, the connection trace 51′ and the device power line 31′ in the via hole are prone to delamination as shown in FIGS. 8, 9 and 10, resulting in poor overlap between the connection trace 51′ and the device power line 31′ and low product yield.

Based on this, as shown in FIGS. 6 and 7, in the array substrate 10 provided in some embodiments of the present disclosure, the first conductive layer 30 includes a plurality of signal lines 310, and the second conductive layer 50 includes a plurality of device conductive portion groups 510 and a plurality of chip conductive portion groups 520.

As shown in FIGS. 3 and 6, the device conductive portion group 510 includes a plurality of first conductive portions 511 disposed at intervals, and the device conductive portion group 510 is configured to be connected to light-emitting device 21.

For example, as shown in FIGS. 3 and 11, the device conductive portion group 510 includes two first conductive portions 511, and the two first conductive portions 511 are respectively an anode conductive portion 512 and a cathode conductive portion 513. Two pins 12 of the light-emitting device 21 may be respectively soldered to two first conductive portions 511 of the device conductive portion group 510 by solder to be fixed on the array substrate 10. Here, the solder includes, for example, tin.

It will be noted that the number of the first conductive portions 511 of the device conductive portion group 510 may be designed depending on the number of the pins of the light-emitting device 21. The number of the first conductive portions 511 of the device conductive portion group 510 may alternatively be three, four or six, etc., but the embodiments of the present disclosure are not limited thereto.

As shown in FIGS. 3 and 6, the chip conductive portion group 520 includes a plurality of second conductive portions 521 disposed at intervals, and the chip conductive portion group 520 is configured to be connected to the microchip 22.

For example, as shown in FIGS. 3, 12 and 13, the chip conductive portion group 520 may include twelve second conductive portions 521, and twelve pins 12 of the microchip 22 may be respectively soldered to the twelve second conductive portions 521 of the chip conductive portion group 520 by solder to be fixed on the array substrate 10. Here, the solder includes, for example, tin.

For example, referring to FIGS. 5, 12 and 13, the chip conductive portion group 520 includes one clock conductive portion CLKP1, one clock relay conductive portion CLKP2, one address conductive portion Di_in, one address relay conductive portion Di_out, one chip power conductive portion VCCP, three ground conductive portions GNDP and four output conductive portions OutP.

It will be noted that the number of the second conductive portions 521 of the chip conductive portion group 520 may be designed depending on the number of the pins of the microchip 22. The number of the second conductive portions 521 of the chip conductive portion group 520 may alternatively be eight, ten or fourteen, etc., but the embodiments of the present disclosure are not limited thereto.

Some embodiments of the present disclosure are schematically described below by taking an example where the device conductive portion group 510 includes two first conductive portions 511 and the chip conductive portion group 520 includes twelve second conductive portions 521, but the embodiments of the present disclosure are not limited thereto.

As shown in FIG. 4, a plurality of signal lines 310 are connected to a plurality of bonding pads P to receive at least one of light emission signals such as a device power signal, a chip power signal, an address signal, a clock signal and a common voltage signal from a circuit board.

For example, referring to FIGS. 5 and 6, the plurality of signal lines 310 include a plurality of device power lines 311, a plurality of common voltage signal lines 312 and a plurality of chip signal lines 313. The plurality of chip signal lines 313 are divided into a plurality of chip signal line groups 3130, and multiple chip signal lines 313 of each chip signal line group 3130 are configured to be connected to the same microchip 22.

The multiple chip signal lines 313 of each chip signal line group 3130 may include a chip power signal line 314, an address signal line 315 and a clock signal line 316. The common voltage signal line 312 is connected to a ground conductive portion GNDP of the chip conductive portion group 520 to provide a common voltage signal, such as a ground signal, to the microchip 22. The address signal line 315 is connected to the address conductive portion Di_in and the address relay conductive portion Di_out of the chip conductive portion group 520 to provide an address signal to the microchip 22. The clock signal line 316 is connected to the clock conductive portion CLKP1 and the clock relay conductive portion CLKP2 of the chip conductive portion group 520 to provide a clock signal to the microchip 22.

On this basis, as shown in FIGS. 5 and 6, the multiple chip signal lines 313 of each chip signal line group 3130 may further include electromagnetic shielding signal lines 317. The electromagnetic shielding signal lines 317 are disposed between the chip power signal line 314 and the clock signal line 316 and between the address signal line 315 and the clock signal line 316, so as to play a role of electromagnetic shielding and improve an anti-interference ability of signal transmission. The electromagnetic shielding signal line 317 may be connected to the common voltage signal line 312 to simplify the circuit structure.

In some embodiments, as shown in FIGS. 5 and 6, the device power lines 311, the common voltage signal lines 312 and the chip signal lines 313 all extend in the first direction X. In the second direction Y, each chip signal line group 3130 is located between two common voltage signal lines 312, and each common voltage signal line 312 is located between a chip signal line group 3130 and a device power line 311.

A device power line 311 may be connected to first conductive portions 511 (anode conductive portions 512) of device conductive portion groups 510 of a column of light-emitting units 210 to provide a power signal to all light-emitting devices 21 in the light-emitting units 210. Referring to FIG. 7, the insulating layers 40 are provided with first via holes H1 extending through the insulating layers 40, and the first conductive portion 511 (the anode conductive portion 512) of the device conductive portion group 510 may be in electrical contact with the device power line 311 through the first via hole H1.

In this case, the first conductive portion 511 of the device conductive portion group 510 is in direct electrical contact with the device power line 311 through the first via hole H1, and the first via hole H1 is located at a lower side of the first conductive portion 511. In this way, due to actions of the gravity of the light-emitting device 21 itself and the extrusion of the die bonding process, the phenomenon of delamination between the first conductive portion 511 in the first via hole H1 and the device power line 311 may be improved, the risk of poor overlap between the first conductive portion 511 in the first via hole H1 and the device power line 311 may be reduced, and the product yield may be improved.

FIG. 14 is a diagram showing a reliability test result of circuit lines located in the second conductive layer in accordance with some embodiments.

It can be seen from FIG. 14, in a case where a thickness of the third passivation layer 44 is 2400 Å and a thickness of the second planarization layer is 3 μm, in the circuit line located in the second conductive layer 50, a portion located inside the via hole will experience corrosion after 168 hours (168 h), and a portion located outside the via hole will experience corrosion after 288 hours (288 h).

It can be seen from FIG. 14, in a case where a thickness of the third passivation layer 44 is 3000 Å and a thickness of the second planarization layer is 3 μm, in the circuit line located in the second conductive layer 50, a portion located inside the via hole will experience corrosion after 504 h, and a portion located outside the via hole will experience corrosion after 750 h.

It can be seen from FIG. 14, in a case where a thickness of the third passivation layer 44 is 4000 Å and a thickness of the second planarization layer is 3 μm, in the circuit line located in the second conductive layer 50, a portion located inside the via hole will experience corrosion after 504 h, and a portion located outside the via hole will experience corrosion after 1000 h.

It can be seen from FIG. 14, in a case where a thickness of the third passivation layer 44 is 4000 Å and a thickness of the second planarization layer is 4 μm, in the circuit line located in the second conductive layer 50, a portion located inside the via hole will experience corrosion after 750 h, and a portion located outside the via hole will experience corrosion after 1000 h.

It can be known based on the above that the greater the thickness of the passivation layer and/or the planarization layer on an upper side of the circuit line, the better the anti-corrosion effect of the circuit line, and the lower the risk of disconnection due to corrosion. Based on this, for the connection between the device power line 311 and the first conductive portion 511 of the device conductive portion group 510, there is no need to provide a connection trace in the second conductive layer 50, which is equivalent to transferring the connection trace connecting the light-emitting device 21 and the device power line 311 in the related art to the first conductive layer 30. In this way, the connection trace is also covered with the insulating layer(s) 40, for example, the connection trace is also covered with a first passivation layer 41, a first planarization layer 42 and a second passivation layer 43, that is, the thickness of the passivation layer and/or the planarization layer covering the connection trace increases, thereby improving the corrosion resistance of the connection trace, reducing the risk of the connection trace being disconnected due to corrosion, and improving the product yield.

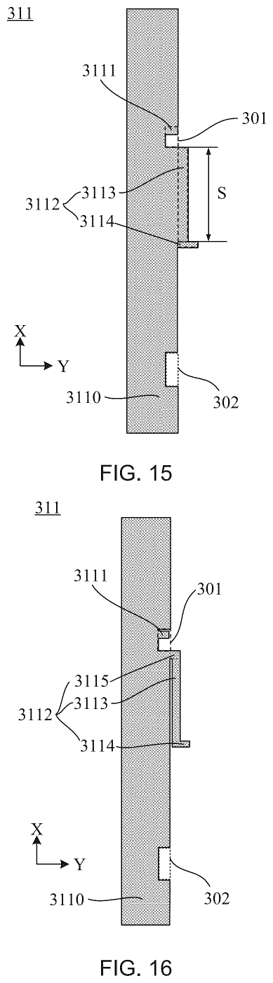

For example, as shown in FIGS. 15 and 16, the device power line 311 includes a main body portion 3110, a first overlapping portion 3111 and a second overlapping portion 3112. The first overlapping portion 3111 and the second overlapping portion 3112 are both connected to the main body portion 3110.

As shown in FIGS. 15 and 16, the main body portion 3110 extends in the first direction X and is connected to a bonding pad P. The main body portion 3110 is, for example, in a shape of a straight strip. In the second direction Y, at least one side of the main body portion 3110 is provided with a plurality of first openings 301 and a plurality of second openings 302 therein; and in the first direction X, the plurality of first openings 301 and the plurality of second openings 302 are provided alternately.

In combination with FIGS. 6, 16 and 17, the light-emitting device 21 may be provided corresponding to the first opening 301 and the second opening 302, that is, the device conductive portion group 510 may be provided corresponding to the first opening 301 and the second opening 302. For example, the light-emitting unit 210 includes a first device conductive portion group 501, a second device conductive portion group 502, a third device conductive portion group 503 and a fourth device conductive portion group 504 that are connected in series sequentially, the first device conductive portion group 501 is connected to a device power line 311, and the fourth device conductive portion group 504 is connected to a chip conductive portion group 520. In this case, in the first direction X, of two adjacent light-emitting units 210, a first device conductive portion group 501 of a light-emitting unit 210 may be disposed at the first opening 301, and a second device conductive portion group 502 of the other light-emitting unit 210 may be disposed at the second opening 302.

On this basis, the first overlapping portion 3111 may be a portion protruding within the first opening 301 of the main body portion 3110, and the second overlapping portion 3112 may be a portion protruding from the straight-striped main body portion 3110.

As shown in FIGS. 6, 15 and 16, the first overlapping portion 3111 is disposed within the first opening 301, and the first overlapping portion 3111 may be connected to a device conductive portion group 510. As shown in FIG. 15, the first overlapping portion 3111 may be connected to an edge of the first opening 301 away from the second overlapping portion 3112. As shown in FIG. 16, the first overlapping portion 3111 may alternatively be spaced apart from the edge of the first opening 301 away from the second overlapping portion 3112. The embodiments of the present disclosure are not specifically limited herein.

As shown in FIGS. 6, 15 and 16, the second overlapping portion 3112 is disposed between the first opening 301 and the second opening 302 that are adjacent. The second overlapping portion 3112 includes a first sub-segment 3113 and a second sub-segment 3114. The first sub-segment 3113 extends in the first direction X, the second sub-segment 3114 extends in the second direction Y, and the first sub-segment 3113 is located on a side of the second sub-segment 3114 proximate to the adjacent first opening 301. The second sub-segment 3114 of the second overlapping portion 3112 may be connected to a device conductive portion group 510.

For example, referring to FIGS. 6, 11 and 16, in the first direction X, in two adjacent light-emitting units 210, a first conductive portion 511 of a target device conductive portion group M of a light-emitting unit 210 is in electrical contact with a first overlapping portion 3111 through a first via hole H1, and a first conductive portion 511 of a target device conductive portion group M of another light-emitting unit 210 is in electrical contact with a second sub-segment 3114 through another first via hole H1.

The target device conductive portion group M is a device conductive portion group 510, in electrical contact with the device power line 311 through the first via hole H1, in the plurality of device conductive portion groups 510. For example, the light-emitting unit 210 includes a first device conductive portion group 501, a second device conductive portion group 502, a third device conductive portion group 503 and a fourth device conductive portion group 504 that are connected in series sequentially, and the target device conductive portion group M is the first device conductive portion group 501.

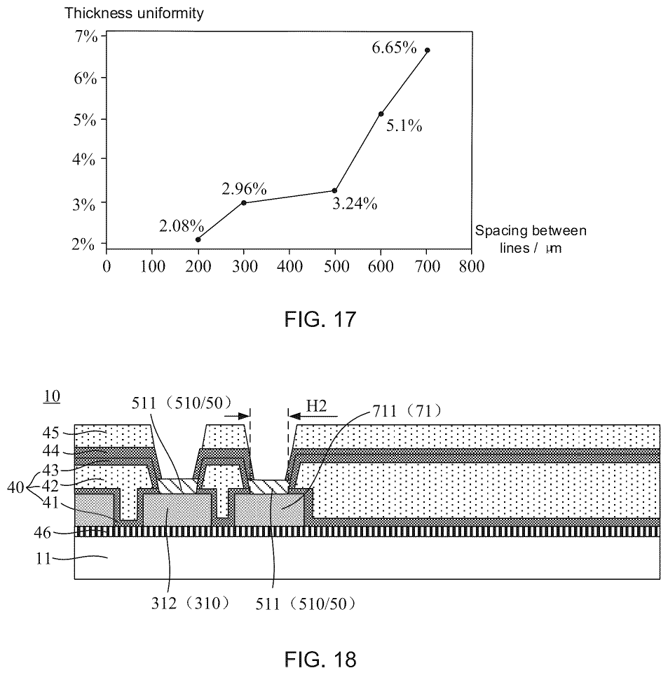

FIG. 17 is a line graph of a spacing between circuit lines in a first conductive layer in the array substrate and a thickness uniformity of the first conductive layer in accordance with some embodiments. It can be seen from FIG. 17 that the smaller the spacing between the circuit lines in the first conductive layer 30, the better the thickness uniformity of the first conductive layer 30.

Based on this, the first sub-segment 3113 is provided between the device power line 311 and the common voltage signal line 312. During manufacturing the first conductive layer 30 by electroplating, it is equivalent to dividing a larger etching gap between the device power line 311 and the common voltage signal line 312 into two smaller etching gaps. The two smaller etching gaps are respectively an etching gap between the device power line 311 and the first sub-segment 3113 and an etching gap between the common voltage signal line 312 and the first sub-segment 3113, thereby shortening the spacing between the adjacent circuit lines.

In this case, when various lines with a relatively large thickness (e.g., greater than or equal to 2 μm) located in the first conductive layer 30 are formed by electroplating, the first sub-segment 3113 may play a role of accompanying plating, so that the device power line 311 and the first sub-segment 3113 have a relatively high thickness uniformity, and the first sub-segment 3113 and the common voltage signal line 312 have a relatively high thickness uniformity, thereby compensating for the thickness difference between the device power line 311 and the first sub-segment 3113 and improving the thickness uniformity of the first conductive layer 30. Moreover, the provision of the first sub-segment 3113 may also reduce the etching time required for patterning the first conductive layer 30, reduce the consumption of etching solution, and reduce the costs.

In addition, referring to FIGS. 15 and 16, an end of the first sub-segment 3113 away from the second sub-segment 3114 may be flush with an edge of the first opening 301 proximate to the second opening 302. In this way, a length of the first sub-segment 3113 in the first direction X may be set relatively large, which may play a good role in compensation and accompanying plating, is conducive to improvement of the thickness uniformity of the first conductive layer 30, and may further reduce the etching time required for patterning the first conductive layer 30, reduce the consumption of etching solution, and reduce the costs.

In some embodiments, referring to FIG. 15, the first sub-segment 3113 may be directly connected to the main body portion 3110. For example, edges, close to each other, of the first sub-segment 3113 and the main body portion 3110 coincide. In this way, there is no gap between the first sub-segment 3113 and the main body portion 3110. When various lines with a relatively large thickness (e.g., greater than or equal to 2 μm) located in the first conductive layer 30 are formed by electroplating, it is beneficial to further improving the thickness uniformity of the first conductive layer 30, and the difficulty of patterning the first conductive layer 30 by etching may be reduced, and the production cost may further be reduced.

In some other embodiments, referring to FIG. 16, there is a gap between the first sub-segment 3113 and the main body portion 3110. The second overlapping portion 3112 further includes a third sub-segment 3115, and the first sub-segment 3113 is connected to the main body portion 3110 by the third sub-segment 3115. It will be noted that a dimension of the third sub-segment 3115 in the second direction Y is slightly greater than a dimension of the first sub-segment 3113 in the second direction Y. In this way, a dimension difference between the third sub-segment 3115 and the first sub-segment 3113 in the second direction Y is a size of a gap between the first sub-segment 3113 and the main body portion 3110.

In some embodiments, referring to FIGS. 6 and 7, the array substrate 10 further includes a plurality of connection lines 60, and multiple device conductive portion groups 510 in the same light-emitting unit 210 are connected by connection lines 60. The at least one connection line 60 is located in the first conductive layer 30.

In this case, at least part of the connection lines 60 between the plurality of device conductive portion groups 510 is located in the first conductive layer 30, which is equivalent to transferring at least part of the connection traces connecting the plurality of device conductive portion groups 510 in the related art to the first conductive layer 30. In this way, the connection trace (the connection line 60 located in the first conductive layer 30) is also covered with the insulating layer(s) 40, for example, the connection trace is also covered with a first passivation layer 41, a first planarization layer 42 and a second passivation layer 43, thereby improving the corrosion resistance of the connection trace (the connection line 60 located in the first conductive layer 30), reducing the risk of the connection trace (the connection line 60 located in the first conductive layer 30) being disconnected due to corrosion, and improving the product yield. In addition, a wiring area of the first conductive layer 30 increases, which is beneficial to improving the thickness uniformity of the first conductive layer 30, reducing the etching time required for patterning the first conductive layer 30, reducing the consumption of etching solution, and reducing the costs.

For example, as shown in FIGS. 6 and 7, the plurality of connection lines 60 include first type of connection lines 610 and second type of connection lines 620. Orthographic projections of the first type of connection lines 610 on the substrate 11 are staggered with orthographic projections of the plurality of signal lines 310 on the substrate 11, and orthographic projections of the second type of connection lines 620 on the substrate 11 at least partially overlap with orthographic projections of the plurality of signal lines 310 on the substrate 11. All the first type of connection lines 610 are located in the first conductive layer 30, and all the second type of connection lines 620 are located in the second conductive layer 50.

A first type of connection line 610 may be located between a device power line 311 and a common voltage signal line 312 that are adjacent to the first type of connection line 610. And/or, a first type of connection line 610 is located between a common voltage signal line 312 and a chip signal line group 3130 that are adjacent to the first type of connection line 610.

For example, as shown in FIG. 6, the light-emitting unit 210 includes a first device conductive portion group 501, a second device conductive portion group 502, a third device conductive portion group 503 and a fourth device conductive portion group 504 that are connected in series sequentially.

On this basis, the plurality of connection lines 60 include a first connection line 61, a second connection line 62 and a third connection line 63. The first connection line 61 and the third connection line 63 are located in the first conductive layer 30, and the second connection line 62 is located in the second conductive layer 50. In this case, the first connection line 61 and the third connection line 63 are first type of connection lines 610, and the second connection line 62 is a second type of connection line 620.

An end of the first connection line 61 is connected to a first device conductive portion group 501, and the other end of the first connection line 61 is connected to a second device conductive portion group 502. An end of the second connection line 62 is connected to the second device conductive portion group 502, and the other end of the second connection line 62 is connected to a third device conductive portion group 503. An end of the third connection line 63 is connected to the third device conductive portion group 503, and the other end of the third connection line 63 is connected to a fourth device conductive portion group 504.

It can be seen from the above that in the array substrate 10 of the embodiments of the present disclosure, connection lines 60 (the first connection line 61 and the third connection line 63) not overlapping with the signal line 310 are arranged in the first conductive layer 30. In this way, not only may the risk of the first connection line 61 and the third connection line 63 being disconnected due to corrosion be reduced, but also it is conducive to improvement of the thickness uniformity of the first conductive layer 30 and reduction of the production costs.

In some embodiments, referring to FIGS. 6, 18 and 12, the chip conductive portion group 520 is located between two adjacent chip signal lines 313 in the same chip signal line group 3130, and the insulating layer(s) 40 are further provided with second via holes H2 and third via holes H3 extending through the insulating layer(s) 40.

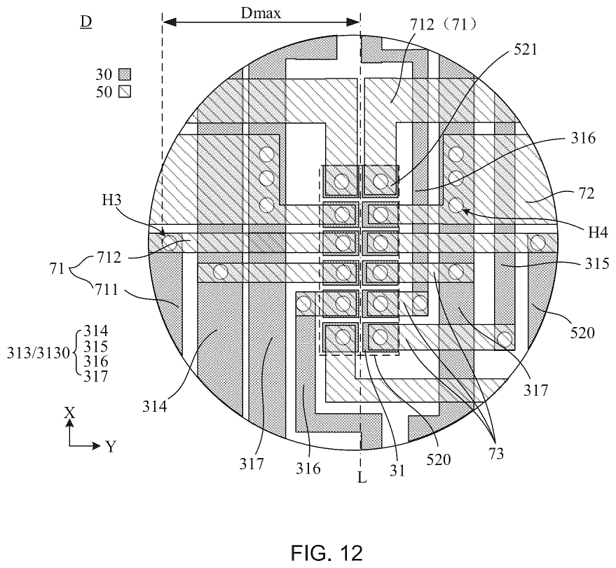

On this basis, referring to FIGS. 6 and 12, the array substrate 10 further includes a plurality of first transfer lines 71, and the first transfer lines 71 include a first trace segment 711 and a second trace segment 712.

As shown in FIGS. 6, 12 and 18, the first trace segment 711 is located between a common voltage signal line 312 and a chip signal line 313 that are adjacent to the first trace segment 711, and the first conductive portion 511 of the device conductive portion group 510 is in electrical contact with the first trace segment 711 through a second via hole H2.

As shown in FIGS. 6 and 12, an end of the second trace segment 712 is electrically connected to the first trace segment 711 through a third via hole H3, and the other end of the second trace segment 712 crosses at least one chip signal line 313 to be connected to a second conductive portion 521 of the chip conductive portion group 520. For example, the second trace segment 712 sequentially crosses the chip power signal line 314, the electromagnetic shielding signal line 317, and the clock signal line 316 to be connected to the second conductive portion 521 of the chip conductive portion group 520. Alternatively, the second trace segment 712 sequentially crosses the address signal line 315, the electromagnetic shielding signal line 317, and the clock signal line 316 to be connected to the second conductive portion 521 of the chip conductive portion group 520.

Based on the above, the first trace segment 711 does not overlap with the signal lines 310, and the second trace segment 712 overlaps with the chip signal line(s) 313. Therefore, the first trace segment 711 may be disposed in the first conductive layer 30, and the second trace segment 712 may be disposed in the second conductive layer 50.

In this case, in the array substrate 10 of the embodiments of the present disclosure, a portion of the first transfer line 71 (the first trace segment 711) that does not overlap with the signal lines 310 is provided in the first conductive layer 30. In this way, not only may the risk of the first trace segment 711 being disconnected due to corrosion be reduced, but also it is conducive to improvement of the thickness uniformity of the first conductive layer 30 and reduction of the production costs.

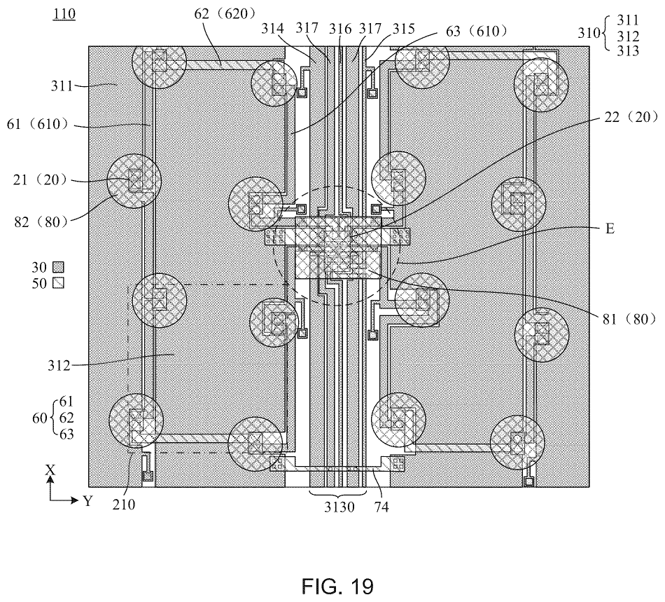

In some embodiments, as shown in FIGS. 6 and 12, the chip conductive portion group 520 has a center line L extending in the first direction X, and a maximum distance Dmax between the third via hole H3 and the center line L is less than or equal to 2 mm. In this case, the third via hole H3 is close to the chip conductive portion group 520, which facilitates the third via hole H3 to be covered by an encapsulation portion 80 (referring to FIG. 19) formed in the subsequent process, so as to improve the waterproofness and corrosion resistance, and reduce the risk of poor overlap between the second trace segment 712 and the first trace segment 711.

For example, referring to FIG. 19, the light-emitting substrate 110 further includes a plurality of encapsulation portions 80 disposed at intervals, and an encapsulation portion 80 wraps at least an electronic component 20 to protect the electronic component 20, thereby improving the waterproofness and corrosion resistance of the light-emitting substrate 110 and the light extraction efficiency of the light-emitting substrate 110.

Maximum lengths of an orthographic projection of the encapsulation portion 80 on the substrate 11 in the first direction X and the second direction Y are each in a range of 1 mm to 4 mm, inclusive. For example, each of the maximum lengths of the orthographic projection of the encapsulation portion 80 on the substrate 11 in the first direction X and the second direction Y is any of 1 mm, 1.5 mm, 2 mm, 2.5 mm, 3 mm, 3.5 mm and 4 mm.

It will be noted that the encapsulation portion 80 may be formed by using a glue dispenser to spray high thixotropic glue onto the electronic component 20 and then undergoing a curing process. Furthermore, the orthographic projection of the encapsulation portion 80 on the substrate 11 may be in a shape of any of a circle, an ellipse, a polygon, or an irregular shape combined with a straight line and a curve, which is not limited in the embodiments of the present disclosure.

It will be understood that the material of the encapsulation portion 80 will be adjusted adaptively for different types of electronic components 20. For example, if the electronic component 20 is an optical component, the encapsulation portion 80 is made of a transparent material; and if the electronic component 20 is a non-optical component, the material of the encapsulation portion 80 has no requirement for light transmittance, and may select a transparent material, a reflective material, or a light-absorbing material.

It will be noted that the transparent material may include transparent silicone, the reflective material may include at least one of white ink, white resin and silicone white adhesive, and the light-absorbing material may include at least one of black ink, black resin and silicone black adhesive.

For example, referring to FIG. 19, the encapsulation portion 80 includes a first encapsulation portion 81 and second encapsulation portions 82. The first encapsulation portion 81 covers the microchip 22, and the second encapsulation portion 82 covers the light-emitting device 21. Furthermore, the material of the first encapsulation portion 81 may use a transparent material, and the material of the second encapsulation portion 82 may use a reflective material, so as to improve the light extraction efficiency of the light-emitting substrate 110.

It will be noted that shapes of the orthographic projections of the second encapsulation portion 82 and the first encapsulation portion 81 on the substrate 11 may be the same or different, which is not limited in the embodiments of the present disclosure.

On this basis, as shown in FIGS. 12, 19 and 20, the first encapsulation portion 81 further covers the third via holes H3. In this way, due to actions of the gravity of the first encapsulation portion 81 itself and the extrusion of the expansion force generated in the curing process, the phenomenon of delamination between the second trace segment 712 in the third via hole H3 and the first trace segment 711 may be improved, thereby reducing the risk of poor overlap between the second trace segment 712 and the first trace segment 711 and improving product yield.

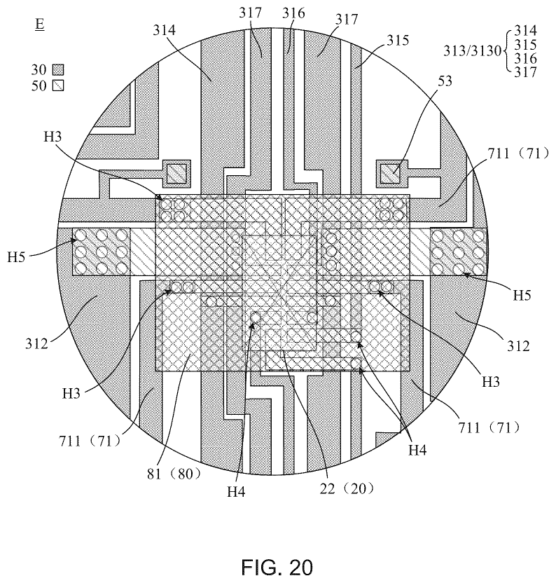

In some embodiments, referring to FIG. 20, the insulating layer(s) 40 are further provided with fourth via holes H4 and fifth via holes h5 extending through the insulating layer(s) 40.

On this basis, referring to FIGS. 6, 12 and 20, the array substrate 10 further includes a plurality of second transfer lines 72 and a plurality of third transfer lines 73, and the plurality of second transfer lines 72 and the plurality of third transfer lines 73 are disposed in the second conductive layer 50.

The second transfer line 72 extends in the second direction Y, an end of the second transfer line 72 is connected to a chip signal line 313 through a fourth via hole h4, and the other end of the second transfer line 72 is connected to a second conductive portion 521 of a chip conductive portion group 520. The third transfer line 73 extends in the second direction Y, an end of the third transfer line 73 is connected to a common voltage signal line 312 through a fifth via H5, and the other end of the third transfer line 73 crosses at least one chip signal line 313 to be connected to a second conductive portion 521 of the chip conductive portion group 520.

On this basis, the above first encapsulation portion 81 may further cover the fourth via holes H4. In this way, due to actions of the gravity of the first encapsulation portion 81 itself and the extrusion of the expansion force generated in the curing process, the phenomenon of delamination between the second transfer line 72 in the fourth via hole H4 and the chip signal line 313 may be improved, thereby reducing the risk of poor overlap between the second transfer line 72 and the chip signal line 313 and improving product yield.

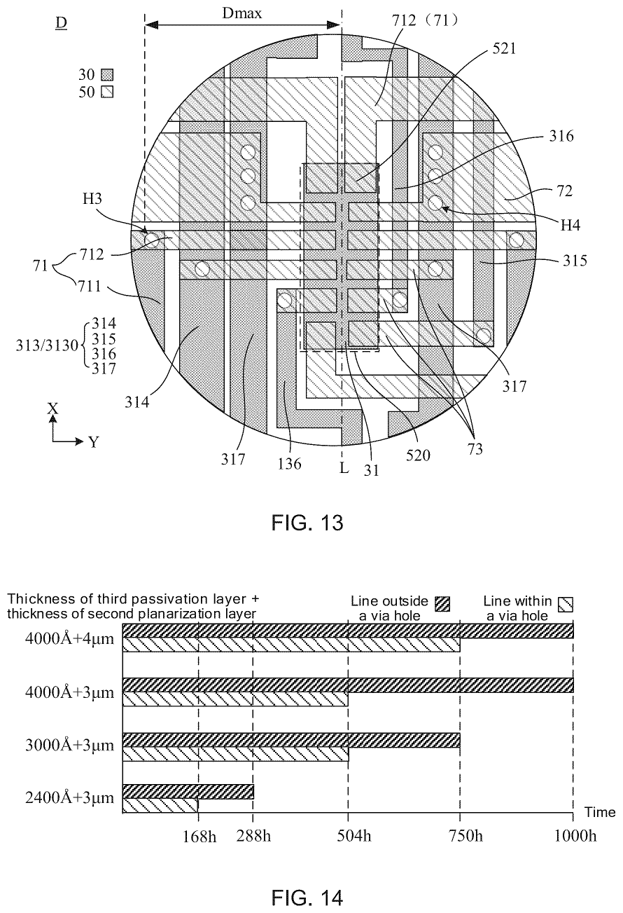

In some embodiments, referring to FIGS. 12 and 13, the array substrate 10 may further include a plurality of first pads 31, and a chip conductive portion group 520 may correspond to a first pad 31 or correspond to multiple first pads 31. The first pads 31 are located in the first conductive layer 30.

In this case, when various lines with a relatively large thickness (e.g., greater than or equal to 2 μm) located in the first conductive layer 30 are formed by electroplating, the first pads 31 may play a role of accompanying plating. In this case, compared with a spacing between traces adjacent to a first pad 31, the first pad 31 and an adjacent trace have a smaller spacing. In this way, the first pad 31 and an adjacent trace have a relatively high thickness uniformity, thereby compensating for the thickness difference between the traces adjacent to the first pad 31, improving the thickness uniformity of the traces adjacent to the first pad 31, and improving the thickness uniformity of the first conductive layer 30.

In some examples, as shown in FIG. 12, an orthographic projection of a second conductive portion 521 of the chip conductive portion group 520 on the substrate 11 is located within an orthographic projection of a first pad 31 on the substrate 11. Moreover, the second conductive portion 521 may be electrically connected to the corresponding first pad 31, or may be electrically insulated from the corresponding first pad 31. For example, the second conductive portion 521 is electrically connected to the corresponding first pad 31. In this way, the first pad 31 may increase a conductive area, thereby reducing resistance and reducing loss of signal transmission.

In some other examples, as shown in FIG. 13, an orthographic projection of a chip conductive portion group 520 on the substrate 11 may be located within an orthographic projection of a first pad 31 on the substrate 11. The insulating layer(s) 40 exist between the chip conductive portion group 520 and the first pads 31. In this way, a chip conductive portion group 520 corresponds to a first pad 31, the process is simple and the manufacture cost is low.

In some embodiments, referring to FIGS. 6, 21 and 22, the second conductive layer 50 further includes third conductive portions 53. The array substrate further includes test lines 90, and the third conductive portion 53 is connected to a signal line 310, a connection line 60 or a first transfer line 71 by a test line 90. The third conductive portion 53 may provide a test point for debugging of lighting, which is convenient for detecting and debugging various signal lines 310, connection lines 60 or first transfer lines 71, and is beneficial to the repair of the light-emitting substrate 110, thereby improving maintainability of the light-emitting substrate 110 and improving the product yield.

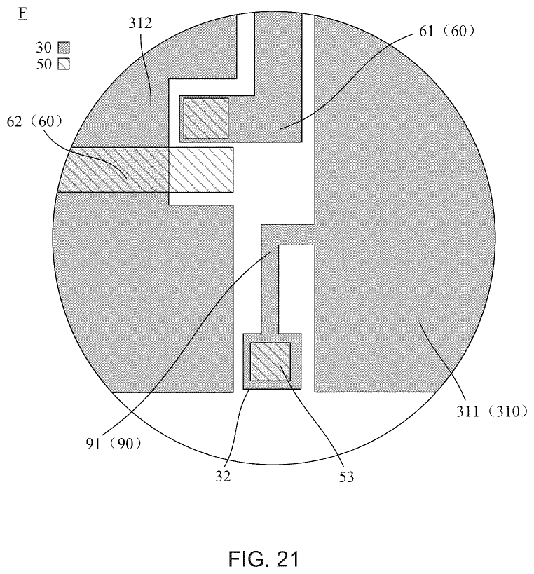

For example, referring to FIGS. 6 and 21, the test lines 90 include a first test line 91, and the third conductive portion 53 is connected to the signal line 310 by the first test line 91. Furthermore, at least one first test line 91 is located in the first conductive layer 30. For example, all the first test lines 91 are located in the first conductive layer 30.

In this case, the first test line 91 is further covered with the insulating layer(s) 40. For example, the first test line 91 is further covered with a first passivation layer 41, a first planarization layer 42 and a second passivation layer 43, thereby improving the corrosion resistance of the first test line 91, reducing the risk of the first test line 91 being disconnected due to corrosion, and improving product yield. In addition, a wiring area of the first conductive layer 30 increases, and the first test line 91 may also play a role of compensation and accompanying plating, which is beneficial to improving the thickness uniformity of the first conductive layer 30, reducing the etching time required for patterning the first conductive layer 30, reducing the consumption of etching solution, and reducing the costs.

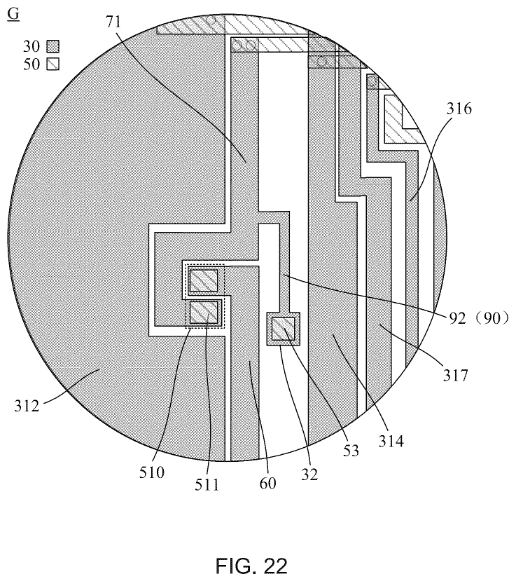

For example, referring to FIGS. 6 and 22, the test lines 90 further include a second test line 92, and the third conductive portion 53 is connected to the connection line 60 or the first transfer line 71 by the second test line 92. Furthermore, at least one second test line 92 is located in the first conductive layer 30. For example, all the second test lines 92 are located in the first conductive layer 30.

In this case, the second test line 92 is further covered with the insulating layer(s) 40. For example, the second test line 92 is further covered with a first passivation layer 41, a first planarization layer 42 and a second passivation layer 43, thereby improving the corrosion resistance of the second test line 92, reducing the risk of the second test line 92 being disconnected due to corrosion, and improving product yield. In addition, a wiring area of the first conductive layer 30 increases, and the second test line 92 may also play a role of compensation and accompanying plating, which is beneficial to improving the thickness uniformity of the first conductive layer 30, reducing the etching time required for patterning the first conductive layer 30, reducing the consumption of etching solution, and reducing the costs.

In some embodiments, referring to FIGS. 21 and 22, the array substrate 10 may further include a plurality of second pads 32, and a second pad 32 corresponds to a third conductive portion 53. The second pads 32 are located in the first conductive layer 30, so that the second pads 32 may also play a role of compensation and accompanying plating, which is beneficial to improving the thickness uniformity of the first conductive layer 30.

For example, as shown in FIGS. 21 and 22, an orthographic projection of a third conductive portion 53 on the substrate 11 is located within an orthographic projection of a second pad 32 on the substrate 11. Furthermore, the third conductive portion 53 is electrically connected to the corresponding second pad 32. In this way, the second pad 32 may increase the conductive area, thereby reducing resistance and reducing the loss of signal transmission.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. An array substrate, comprising:
a substrate;
a first conductive layer disposed on a side of the substrate, wherein the first conductive layer includes a plurality of signal lines, and the plurality of signal lines include a plurality of device power lines;
at least one insulating layer disposed on a side of the first conductive layer away from the substrate, wherein the at least one insulating layer is provided with first via holes extending through the at least one insulating layer; and
a second conductive layer disposed on a side of the at least one insulating layer away from the substrate, wherein the second conductive layer includes a plurality of device conductive portion groups and a plurality of chip conductive portion groups, a device conductive portion group includes a plurality of first conductive portions disposed at intervals, and the device conductive portion group is configured to be connected to a light-emitting device; a chip conductive portion group includes a plurality of second conductive portions disposed at intervals, and the chip conductive portion group is configured to be connected to a microchip; and a first conductive portion of the device conductive portion group is in electrical contact with a device power line through a first via hole.

2. The array substrate according to claim 1, wherein the array substrate comprises a plurality of light-emitting units and a plurality of connection lines; a light-emitting unit includes multiple device conductive portion groups connected in series and/or in parallel in the plurality of device conductive portion groups, and the multiple device conductive portion groups in the same light-emitting unit are connected by connection lines; and at least one connection line is located in the first conductive layer.

3. The array substrate according to claim 2, wherein the plurality of connection lines include first type of connection lines and second type of connection lines; orthographic projections of the first type of connection lines on the substrate are staggered with orthographic projections of the plurality of signal lines on the substrate, and orthographic projections of the second type of connection lines on the substrate at least partially overlap with the orthographic projections of the plurality of signal lines on the substrate; all the first type of connection lines are located in the first conductive layer, and all the second type of connection lines are located in the second conductive layer.

4. The array substrate according to claim 3, wherein the plurality of signal lines further include a plurality of common voltage signal lines and a plurality of chip signal lines; the plurality of chip signal lines are divided into a plurality of chip signal line groups, and multiple chip signal lines of each chip signal line group are configured to be connected to a same microchip;
the plurality of device power lines, the plurality of common voltage signal lines and the plurality of chip signal lines all extend in a first direction; in a second direction, each chip signal line group is located between two common voltage signal lines, and each common voltage signal line is located between a chip signal line group and a device power line; the first direction intersects the second direction; and
a first type of connection line is located between the device power line and a common voltage signal line that are adjacent to the first type of connection line; and/or another first type of connection line is located between the common voltage signal line and a chip signal line group that are adjacent to the another first type of connection line.

5. The array substrate according to claim 2, wherein the light-emitting unit includes a first device conductive portion group, a second device conductive portion group, a third device conductive portion group and a fourth device conductive portion group; the first device conductive portion group is connected to the device power line, and the fourth device conductive portion group is connected to the chip conductive portion group;
the plurality of connection lines include:
a first connection line, an end of the first connection line being connected to the first device conductive portion group, and another end of the first connection line being connected to the second device conductive portion group; the first connection line being located in the first conductive layer;
a second connection line, an end of the second connection line being connected to the second device conductive portion group, and another end of the second connection line being connected to the third device conductive portion group; the second connection line being located in the second conductive layer; and
a third connection line, an end of the third connection line being connected to the third device conductive portion group, and another end of the third connection line being connected to the fourth device conductive portion group; the third connection line being located in the first conductive layer.

6. The array substrate according to claim 1, wherein the device power line includes:
a main body portion extending in a first direction, wherein in a second direction, at least one side of the main body portion is provided with a plurality of first openings and a plurality of second openings therein, and in the first direction, the plurality of first openings and the plurality of second openings are disposed alternately; the first direction intersects the second direction;
a first overlapping portion connected to the main body portion and located at a first opening; and
a second overlapping portion connected to the main body portion and located between the first opening and a second opening that are adjacent, wherein the second overlapping portion includes a first sub-segment and a second sub-segment; the first sub-segment extends in the first direction, the second sub-segment extends in the second direction, and the first sub-segment is located on a side of the second sub-segment proximate to the adjacent first opening.

7. The array substrate according to claim 6, wherein edges, close to each other, of the first sub-segment and the main body portion coincide; or
the first sub-segment and the main body portion have a gap therebetween; the second overlapping portion further includes a third sub-segment, and the first sub-segment is connected to the main body portion by the third sub-segment.

8. The array substrate according to claim 6, wherein an end of the first sub-segment away from the second sub-segment is flush with an edge of the first opening proximate to the second opening.

9. The array substrate according to claim 6, wherein the array substrate comprises a plurality of light-emitting units, and the plurality of light-emitting units are arranged in an array in the first direction and the second direction; the light-emitting units each include multiple device conductive portion groups connected in series and/or in parallel in the plurality of device conductive portion groups, the multiple device conductive portion groups include a target device conductive portion group, and the target device conductive portion group is the device conductive portion group, in electrical contact with the device power line through the first via hole, in the multiple device conductive portion groups; and
in the first direction, in two adjacent light-emitting units, a first conductive portion of a target device conductive portion group of a light-emitting unit is in electrical contact with the first overlapping portion through a first via hole, and a first conductive portion of a target device conductive portion group of another light-emitting unit is in electrical contact with the second sub-segment through another first via hole.

10. The array substrate according to claim 1, wherein the plurality of signal lines further include a plurality of chip signal lines and a plurality of common voltage signal lines; the plurality of chip signal lines are divided into a plurality of chip signal line groups, and multiple chip signal lines of each chip signal line group are configured to be connected to a same microchip; the plurality of device power lines, the plurality of common voltage signal lines and the plurality of chip signal lines all extend in a first direction; in a second direction, each chip signal line group is located between two common voltage signal lines, and each common voltage signal line is located between a chip signal line group and a device power line; the first direction intersects the second direction;
the chip conductive portion group is located between two adjacent chip signal lines in a same chip signal line group; the at least one insulating layer is further provided with second via holes and third via holes extending through the at least one insulating layer; the array substrate further comprises a plurality of first transfer lines, and a first transfer line includes:
a first trace segment disposed in the first conductive layer and located between a common voltage signal line and a chip signal line that are adjacent to the first trace segment; a first conductive portion of the device conductive portion group being in electrical contact with the first trace segment through a second via hole; and
a second trace segment disposed in the second conductive layer; an end of the second trace segment being in electrical contact with the first trace segment through a third via hole, and another end of the second trace segment crossing at least one chip signal line to be connected to a second conductive portion of the chip conductive portion group.

11. The array substrate according to claim 10, wherein the chip conductive portion group has a center line extending in the first direction; and a maximum distance between the third via hole and the center line is less than or equal to 2 mm.

12. The array substrate according to claim 10, wherein the at least one insulating layer is further provided with fourth via holes and fifth via holes extending through the at least one insulating layer;
the array substrate further comprises:
a plurality of second transfer lines disposed in the second conductive layer; an end of a second transfer line being connected to the chip signal line through a fourth via hole, and another end of the second transfer line being connected to a second conductive portion of the chip conductive portion group; and
a plurality of third transfer lines disposed in the second conductive layer; an end of a third transfer line being connected to the common voltage signal line through a fifth via hole, and another end of the third transfer line crossing at least one chip signal line to be connected to a second conductive portion of the chip conductive portion group.

13. The array substrate according to claim 1, wherein the second conductive layer further includes a third conductive portion; the array substrate further comprises:
first test lines, wherein the third conductive portion is connected to a signal line by a first test line, and at least one first test lines is located in the first conductive layer.

14. The array substrate according to claim 13, wherein the array substrate comprises a plurality of light-emitting units, a plurality of connection lines and a plurality of first transfer lines; a light-emitting unit includes multiple device conductive portion groups connected in series and/or in parallel in the plurality of device conductive portion groups, and the multiple device conductive portion groups in the same light-emitting unit are connected by connection lines; and the light-emitting unit is connected to the chip conductive portion group by a first transfer line; and
the array substrate further comprises:
second test lines, wherein the third conductive portion is connected to a connection line or the first transfer line by a second test line; and at least one second test line is located in the first conductive layer.

15. The array substrate according to claim 1, wherein the at least one insulating layer includes a first passivation layer, a first planarization layer and a second passivation layer that are disposed sequentially, and the second passivation layer is disposed on a side of the first planarization layer away from the first conductive layer; and/or
the array substrate further comprises a third passivation layer, and the third passivation layer is disposed on a side of the second conductive layer away from the substrate.

16. A light-emitting substrate, comprising:
the array substrate according to claim 1;
a light-emitting device connected to the device conductive portion group of the array substrate; and
a microchip connected to the chip conductive portion group of the array substrate.

17. The light-emitting substrate according to claim 16, further comprising:
a first encapsulation portion covering the microchip.

18. A backlight module, comprising:
the light-emitting substrate according to claim 16, the light-emitting substrate having a light-exit side and a non-light-exit side that are opposite to each other; and
a plurality of optical films disposed on the light-exit side of the light-emitting substrate.

19. A display apparatus, comprising:
the backlight module according to claim 18; and
a display panel disposed on a side of the plurality of optical films in the backlight module away from the light-emitting substrate.

20. The light-emitting substrate according to claim 17, wherein the at least one insulating layer is further provided with a third via hole and a fourth via hole extending through the at least one insulating layer, and the first encapsulation portion further covers the third via hole and the fourth via hole.
